(19) United States
(12) Patent Application Publication
(10) Pub. No.: US 2011/0156041 A1
(43) Pub. Date: Jun. 30, 2011

(54) POLYMER SUBSTRATE AND METHOD OF FORMING THE SAME AND DISPLAY DEVICE INCLUDING THE POLYMER SUBSTRATE AND METHOD OF MANUFACTURING THE DISPLAY DEVICE

(75) Inventors: Sung-Guk An, Yongin-City (KR); Dong-Un Jin, Yongin-City (KR); Kie Hyun Nam, Yongin-City (KR); Sang-Joon Seo, Yongin-City (KR); Tae-Woong Kim, Yongin-City (KR); Jae-Seob Lee, Yongin-City (KR)

(73) Assignee: SAMSUNG MOBILE DISPLAY CO. LTD., Yongin-City-Gyunggi-Do (KR)

(21) Appl. No.: 12/968,688

(22) Filed: Dec. 15, 2010

(30) Foreign Application Priority Data
Dec. 24, 2009 (KR) 10-2009-0131166

(51) Int. Cl. H01L 51/52; C08G 73/10; C08F 20/10; C08G 63/66; C08G 64/00; C08G 61/10; C08G 75/23; C08B 15/00; C08F 114/08; C08F 114/22; C08F 210/02; B05D 3/02; H01L 21/31

(52) U.S. Cl. 257/59; 528/322; 526/319; 528/271; 528/272; 528/396; 528/391; 536/56; 526/343; 526/255; 526/348.8; 427/372.2; 438/778; 257/40; 257/E51.018; 257/E21.24

(57) ABSTRACT

A polymer substrate having a weight loss of less than about 1% based on an initial weight at a temperature ranging from about 420° C. to about 600° C., a method for forming the polymer substrate, a display device including the polymer substrate, and a method for manufacturing the display device. The method for forming the polymer substrate includes preparing the polymer layer and performing an annealing process to the polymer layer at a temperature greater than about 350° C.

### CLAIM OF PRIORITY

This application makes reference to, incorporates the same herein, and claims all benefits accruing under 35 U.S.C.§119 from an application earlier filed in the Korean Intellectual Property Office on 24 Dec. 2009 and there duly assigned Ser. No. 10-2009-0131166.

### BACKGROUND OF THE INVENTION

1. Field of the Invention

This disclosure relates to a polymer substrate and a method of forming the same, a display device including the polymer substrate, and a method of manufacturing the display device.

2. Description of the Related Art

Flat panel display device, such as organic light emitting diode display (OLED) device, includes an electronic device such as a thin film transistor and an organic light emitting element. The electronic device is formed on a substrate.

### SUMMARY OF THE INVENTION

According to one aspect of the present invention, there is provided a polymer substrate for a display device which has a low thermal expansion rate and is capable of reducing outgassing at a high temperature.

According to another aspect of the present invention, there is provided a method for forming the polymer substrate.

According to another aspect of the present invention, there is provided a display device which includes the polymer substrate.

According to another aspect of the present invention, there is provided a method for manufacturing the display device.

According to one aspect of the present invention, there is provided a polymer substrate having a weight loss of less than about 1% based on an initial weight at a temperature ranging from about 420° C. to about 600° C. The weight loss may range from about 0.000001% to about 0.95% based on an initial weight. The polymer substrate may have a thermal expansion coefficient ranging from about 1 ppm/° C. to about 50 ppm/° C.

According to another aspect of the present invention, there is provided a method of producing a polymer substrate, including preparing a polymer layer and annealing the polymer layer at a temperature higher than about 350° C. The annealing of the polymer layer may be performed at a temperature ranging from about 350° C. to about 500° C. The annealed polymer layer may have a thermal expansion coefficient ranging from about 1 ppm/° C. to about 50 ppm/° C. The annealed polymer layer may have a weight loss of less than about 1% based on an initial weight at a temperature ranging from about 420° C. to about 600° C. The method may further include forming a substrate protective layer on the polymer layer after the annealing of the polymer layer.

According to another aspect of the present invention, there is provided a display device that includes a polymer substrate having a weight loss of less than about 1% based on an initial weight at a temperature ranging from about 420° C. to about 600° C. and an electronic device arranged on the polymer substrate. The weight loss may range from about 0.000001% to about 0.95% based on an initial weight. The polymer substrate may have a thermal expansion coefficient of about 1 ppm/° C. to about 50 ppm/° C. The electronic device may include at least one of a thin film transistor and an organic light emitting element. The thin film transistor may include a control electrode, a semiconductor overlapping the control electrode, a gate insulating layer arranged between the control electrode and the semiconductor and an input electrode and an output electrode electrically connected to the semiconductor, wherein the gate insulating layer comprises tetraethyl orthosilicate (TEOS).

According to another aspect of the present invention, there is provided a method for manufacturing a display device that includes preparing a polymer substrate, annealing the polymer substrate at a temperature greater than about 350° C. and forming an electronic device on the annealed polymer substrate. The annealing of the polymer substrate may be performed at a temperature ranging from about 350° C. to about 500° C. The electronic device may be produced at a temperature greater than about 350° C. The forming of the electronic device can include forming a gate insulating layer, the gate insulating layer comprises tetraethyl orthosilicate (TEOS) at a temperature greater than about 350° C. The method may also include forming a substrate protective layer on the polymer substrate after the annealing of the polymer substrate. According to another aspect of the present invention, there is provided a display device that includes a polymer substrate having a thermal expansion coefficient ranging from 1 ppm/° C. to 50 ppm/° C., thin film transistor formed on the polymer substrate, and an organic light emitting element electrically connected to the thin film transistor.

### BRIEF DESCRIPTION OF THE DRAWINGS

A more complete appreciation of the invention and many of the attendant advantages thereof, will be readily apparent as the same becomes better understood by reference to the following detailed description when considered in conjunction with the accompanying drawings in which like reference symbols indicate the same or similar components, wherein:

FIGS. 1 to 3 are cross-sectional views illustrating a method for forming a polymer substrate;

FIG. 4 is a graph showing a weight loss based on the temperature of a polymer substrate in accordance with an embodiment;

FIG. 5 is a graph showing a weight loss based on the temperature of a polymer substrate according to a Comparative Example; and

FIG. 6 is a cross-sectional view illustrating an organic light emitting diode (OLED) display device in accordance with one embodiment.

### DETAILED DESCRIPTION OF THE INVENTION

This disclosure will he more fully described hereinafter with reference to the accompanying drawings, in which exemplary embodiments of this disclosure are shown. As those skilled in the art would realize, the described embodiments may be modified in various different ways, all without departing from the spirit or scope of this disclosure.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

A flat panel display device, such as organic light emitting diode display (OLED) device, includes an electronic device such as a thin film transistor and an organic light emitting element. The electronic device is formed on a substrate.

As for the substrate, a glass substrate is usually used. The glass substrate has limitations in realizing a large-screen display and portability, because it is heavy and fragile. Also, since the glass substrate may be damaged by external impact, it may not be used for a flexible display device.

Recently, researchers are studying to develop a flat panel display device using a polymer substrate which is not only light in weight and strong to impact but also flexible as well. Since the polymer substrate is formed of a flexible plastic material, it has many advantages, such as portability, safety and lightness, compared with a glass substrate. Also, since the polymer substrate may be formed through a deposition or a printing process, production cost may be cut down. Also, differently from a sheet-based process, a display device may be manufactured through a roll-to-roll process. Thus, it is possible to mass-produce display devices at low cost.

A polymer substrate, however, has high outgassing at a high temperature due to the intrinsic characteristics of a plastic material. The outgassing may affect a thin film formed on the polymer substrate to thereby deteriorate the characteristic of a device. The residue of the outgassing may remain in a chamber and contaminate the chamber during a process. Accordingly, when a device is formed on a polymer substrate, there is a limit in temperature, and when a device is fabricated at a temperature which is not sufficiently high, the characteristics of the device may be deteriorated.

First, a polymer substrate for a display device according to one embodiment will be described. The polymer substrate for a display device according to one embodiment has a weight loss of lower than about 1% based on an initial weight at a temperature ranging from about 420° C. to about 600° C. Herein, the weight loss is a percentage of a weight difference between a polymer substrate before annealing and a polymer substrate after annealing based on the initial weight of the polymer substrate before annealing.

The weight loss being lower than about 1% signifies that the amount lost by outgassing is smaller than 1% of the initial weight. In short, it means that the amount of outgassing is small.

The polymer substrate may go through annealing in advance at a temperature higher than about 350° C. in order to reduce the amount of outgassing from the polymer substrate. The annealing may be performed at a temperature ranging from about 350° C. to about 500° C.

By annealing the polymer substrate in advance, it is possible to reduce the amount of outgassing from the polymer substrate in a subsequent process for forming a thin film on the polymer substrate at a high temperature.

Hereafter, a method for forming a polymer substrate for a display device will be described with reference to the accompanying drawings.

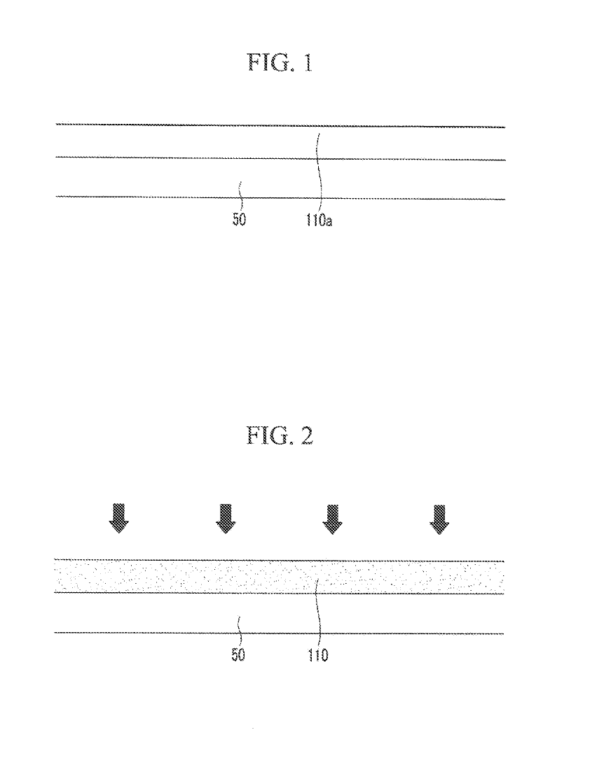

FIGS. 1 to 3 are cross-sectional views illustrating a method for forming a polymer substrate. First, a polymer layer 110a is formed on a glass plate 50. The polymer layer 110a may be made out of polyimide, polyacrylate, polyethyleneetherphthalate, polyethylenenaphthalate, polycarbonate, polyarylate, polyetherimide, polyethersulfone, triacetic acid cellulose, polyvinylidene chloride, polyvinylidene fluoride, ethylene-vinylalcohol copolymer, or a combination thereof. The polymer layer 110a may be produced by coating the glass plate 50 with a polymer resin solution.

Referring to FIG. 2, the polymer substrate 110 is formed by annealing the polymer layer 110a at a temperature of higher than about 350° C. According to one embodiment, the polymer substrate 110 is formed by annealing the polymer layer 110a at a temperature of about 350° C. to about 500° C. Herein, the annealing may be performed at a uniform temperature within the above temperature range or it may be performed while varying the temperature over time within the above temperature range. For example, the annealing may be performed at a temperature of about 380° C. for about 1 minute to 5 hours, or it may be performed by varying the temperature between about 350° C., about 380° C., about 400° C. and about 420° C. for about 1 minute to about 5 hours.

Referring to FIG. 3, the glass plate 50 is removed from the polymer substrate 110. However, when a device including a thin film is formed on the polymer substrate 110, the glass plate 50 may be used as a support to prevent the polymer substrate from being damaged during a process. In this case, the glass plate 50 may be removed from the polymer substrate after the device fabrication process is completed.

The annealed polymer substrate 110 has a relatively low thermal expansion coefficient of about 1 ppm/° C. to about 50 ppm/° C. Therefore, since the annealed polymer substrate 110 has a small heat-based deformation in a subsequent process, the polymer substrate 110 is not deformed much by heat even though the subsequent process subjects the polymer substrate 110 to a high temperature.

The weight loss of the annealed polymer substrate 110 may be lower than about 1% at a temperature ranging from about 420° C. to about 600° C. Therefore, the effect of the outgassing of the polymer substrate 110 during the subsequent process may be reduced.

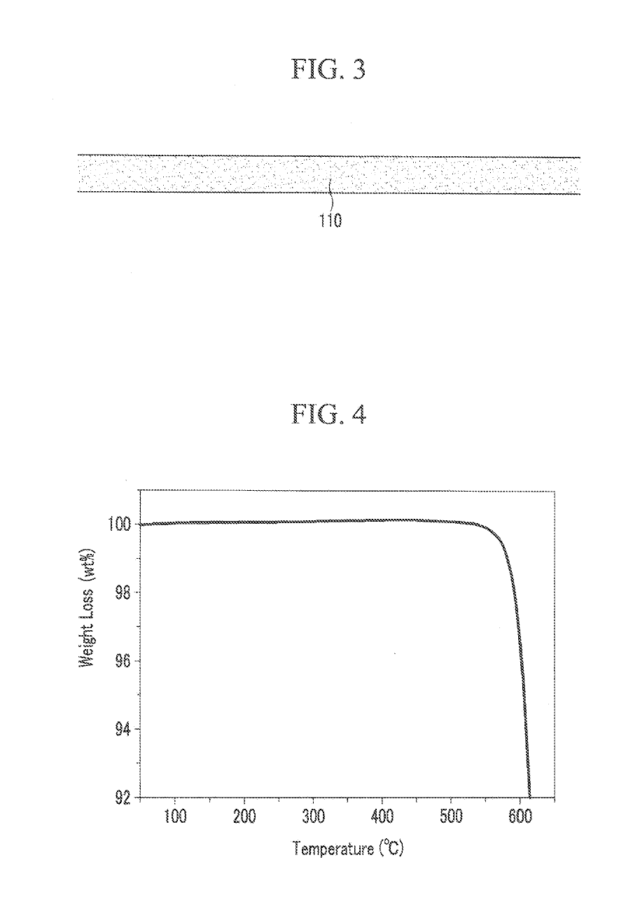

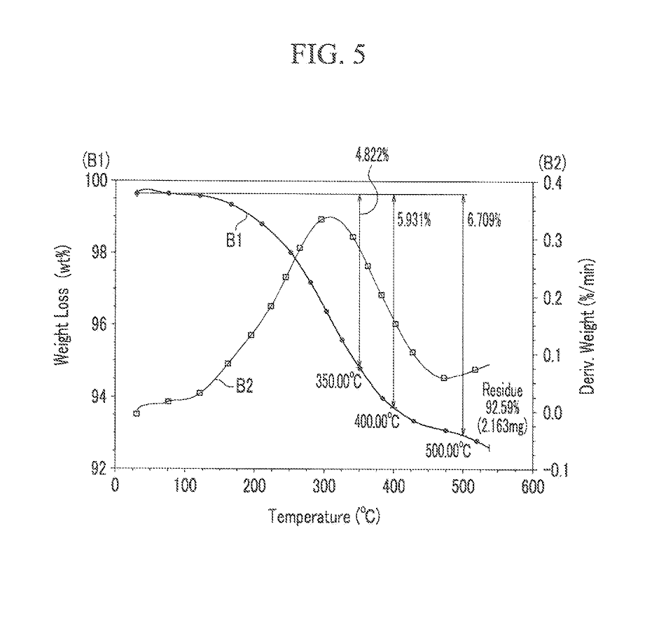

Hereafter, the present invention will be described with reference to FIGS. 4 and 5. FIG. 4 is a graph showing a weight loss based on the temperature of a polymer substrate in accordance with an embodiment and FIG. 5 is a graph showing a weight loss based on the temperature of a polymer substrate according to a Comparative Example.

According to one embodiment, a polymer substrate is formed by coating a glass plate with a polymer solution and gradually annealing from a room temperature (about 25° C.) to about 620° C. According to another embodiment, a glass plate coated with a polymer solution is heated from a room temperature (about 25° C.) to about 150° C. at a speed of about 5° C./min, and annealed at about 150° C. for about 30 minutes. Subsequently, the glass plate coated with the polymer solution is heated up to about 350° C. and annealed at about 350° C. for about 30 minutes and then heated up to about 380° C. and annealed at about 380° C. for about 30 minutes. The amount of loss caused by outgassing, which is the weight loss of the polymer substrate, is measured while heating the annealed polymer substrate from a room temperature (about 25° C.) to about 620° C.

Referring to FIG. 4, the polymer substrate annealed according to one embodiment scarcely shows a weight loss until the annealed polymer substrate is heated to about 550° C. and shows a weight loss of lower than about 1% until a temperature of about 600° C.

One the other hand, referring to FIG. 5, according to Comparative Example, the amount of loss caused by outgassing, which is the weight loss of the polymer substrate, is measured while annealing a polymer substrate that is not annealed from a room temperature (about 25° C.) to about 620° C.

In FIG. 5, B1 denotes the weight loss based on the temperature, and B2 denotes a weight loss variation rate based on time. Referring to FIG. 5, according to Comparative Example, a polymer substrate that is not annealed is measured to have weight loss of about 4.822%, 5.931% and 6.709% at about 350° C., 400° C. and 500° C., respectively.

As described above, when the polymer substrate goes through annealing at a temperature higher than about 350° C., it is thermally stabilized. Thus, the amount of outgassing from the polymer substrate is reduced during a subsequent process performed at a high temperature.

Hereafter, a display device manufactured according to another embodiment will be described with reference to the accompanying drawing. Herein, an organic light emitting diode (OLED) display device is taken as an exemplary display device, but the present invention may be applied all display devices capable of adopting a polymer substrate.

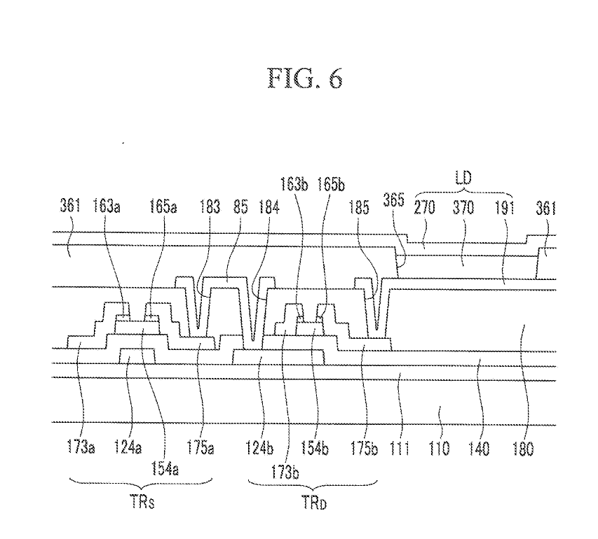

FIG. 6 is a cross-sectional view illustrating an organic light emitting diode (OLED) display device in accordance with an embodiment. The organic light emitting diode (OLED) display device includes a plurality of signal lines and a plurality of pixels which are electrically connected to the plurality of the signal lines and arranged in the form of matrix.

The signal lines include a plurality of gate lines for transferring gate signals (or scan signals), a plurality of data lines for transferring data signals, and a plurality of driving voltage lines for transferring driving voltages.

Each pixel includes a switching transistor (TRs), a driving transistor (TRD) and an organic light emitting element LD. The switching transistor (TRs) includes a control terminal, an input terminal and an output terminal. The control terminal is electrically connected to a gate line and the input terminal is connected to a data line, while the output terminal is connected to a driving transistor (TRD). The switching transistor (TRs) transfers a data signal applied to the data line to the driving transistor (TRD) in response to a scan signal applied to the gate line.

The driving transistor (TRD) also includes a control terminal, an input terminal and an output terminal. The control terminal is connected to the switching transistor (TRs), and the input terminal is connected to a driving voltage line, while the output terminal is connected to the organic light emitting element LD. The driving transistor (TRD) outputs an output current whose intensity is different according to the voltage between the control terminal and the output terminal.

The organic light emitting element LD includes an anode connected to the output terminal of the driving transistor (TRD) and a cathode connected to common voltage. The organic light emitting element LD displays an image by emitting light of different intensities based on the output current of the driving transistor (TRD).

Referring to FIG. 6, a structure of an organic light emitting diode (OLED) display device will be described hereafter. A substrate protective layer 111 is formed on a polymer substrate 110.

As described above, the polymer substrate 110 has gone through annealing at a temperature of higher than about 350° C. in advance. The annealed polymer substrate 110 has a small amount of outgassing at temperatures higher than about 350° C. According to one embodiment, the weight loss at about 350° C. to about 500° C. may be lower than about 1% based on an initial weight. The annealed polymer substrate 110 may have a thermal expansion coefficient of about 1 ppm/° C. to about 50 ppm/° C.

The substrate protective layer 111 may include an inorganic material, an organic material, or a combination thereof. According to one embodiment, the substrate protective layer 111 may include silicon oxide (SiO2), silicon nitride (SiNx), or a combination thereof.

On top of the substrate protective layer 111, a gate conductor including a gate line (not shown) including a first control electrode 124a and a second control electrode 124b is formed.

A gate insulating layer 140 is formed on the gate conductor. The gate insulating layer 140 may be made out of a silicon-based insulating material.

On top of the gate insulating layer 140, a first semiconductor 154a made out of a hydrogenated amorphous silicon or polysilicon and a second semiconductor 154b are formed. The first semiconductor 154a and the second semiconductor 154b are positioned on top of the first control electrode 124a and the second control electrode 124b, respectively.

On top of the first semiconductor 154a, a pair of first ohmic contacts 163a and 165a are formed, while a pair of second ohmic contacts 163b and 165b are formed on top of the second semiconductor 154b.

On top of the ohmic contacts (163a, 163b, 165a, 165b) and the gate insulating layer 140, a data conductor including a plurality of first and second input electrodes 173a and 173b and first and second output electrodes 175a and 175b are formed. The first input electrode 173a is connected to the data line, and the second input electrode 173b is connected to the driving voltage line.

A protective layer 180 is formed on the data conductor. The protective layer 180 includes a plurality of contact holes 183, 184, and 185.

On top of the protective layer 180, a pixel electrode 191 and a connecting member 85 are formed. The pixel electrode 191 is electrically connected to the second output electrode 175b through the contact hole 185, and the connecting member 85 electrically connects the second control electrode 124b and the first output electrode 175a through the contact holes 183 and 184.

Barrier ribs 361 are formed over the protective layer 180, the pixel electrode 191 and the connecting member 85, and the barrier ribs 361 define an opening 365 by surrounding the edge circumference of the pixel electrode 191.

An organic emission layer 370 is formed on the opening 365. At least one auxiliary layer (not shown) may be formed in the upper and/or lower portions of the organic emission layer 370.

A common electrode 270 may be formed on the organic emission layer 370. Of the pixel electrode 191 and the common electrode 270, one may be an anode and the other may be a cathode.

Hereafter, a method for manufacturing the above-described organic light emitting diode (OLED) display device will be described with reference to FIGS. 1 to 3 and FIG. 6.

A polymer layer 110a is formed on a glass plate 50. The polymer layer 110a may be made out of polyimide, polyacrylate, polyethyleneetherphthalate, polyethylenenaphthalate, polycarbonate, poly arylate, polyetherimide, polyethersulfone, triacetic acid cellulose, polyvinylidene chloride, polyvinylidene fluoride, an ethylene-vinylalcohol copolymer, or a combination thereof. The polymer layer 110a may be produced by coating the glass plate 50 with a polymer resin solution.

Subsequently, the polymer layer 110a is gradually annealed starting from room temperature, and annealing is performed at a temperature in excess of about 350° C. For example, the annealing may be performed at a temperature ranging from about 350° C. to about 500° C. to thereby form a polymer substrate 110. Herein, the annealing may be performed at a uniform temperature or it may be performed by varying the temperature in the above temperature range over time. For example, the annealing may be performed at about 380° C. for 1 minute to 5 hours, or the annealing may be performed while varying the temperature between about 350° C., about 380° C., about 400° C. and about 420° C. for about 1 minute to about 5 hours.

Subsequently, a substrate protective layer 111 is formed on the annealed polymer substrate 110. The substrate protective layer 111 may be applied via chemical vapor deposition (CVD) or sputtering, or it may be applied via a solution process such as spin coating.

A conductor is deposited and patterned on the substrate protective layer 111 to thereby form first and second control electrodes 124a and 124b.

Subsequently, a gate insulating layer 140 is formed on the first and second control electrodes 124a and 124b and the substrate protective layer 111. The gate insulating layer 140 may be made out of a silicon-based insulating material, and tetraethyl orthosilicate (TEOS) may be used as a precursor for the silicon-based insulating material. Tetraethyl to orthosilicate precursor of the silicon-based insulating material may improve the characteristics of a thin film transistor and improve stability, compared to when silane is used as a precursor.

Tetraethyl orthosilicate may be deposited at a relatively high temperature of higher than about 350° C. According to one embodiment, tetraethyl orthosilicate may be deposited at a temperature ranging from about 350 to about 550° C. The annealed polymer substrate 110 described above has a small amount of outgassing and a low thermal expansion rate at a high temperature of higher than about 350° C. Thus, tetraethyl orthosilicate, which requires a high temperature process, may be included as a source gas of the gate insulating layer. Therefore, it is possible to prevent the polymer substrate from being deformed while improving the device characteristics by using the gate insulating layer. Also, the stability of a device may be secured by reducing the amount of outgassing.

Subsequently, first and second semiconductors 154a and 154b and first and second ohmic contacts 163a, 165a, 163b, and 165b are formed by depositing amorphous silicon or polysilicon on the gate insulating layer 140. Next, a protective layer 180 is stacked and patterned to thereby form a plurality of contact holes 183, 184, and 185. Then, a pixel electrode 191 is formed on the protective layer 180, and barrier ribs 361 are stacked on the pixel electrode 191. Subsequently, an organic emission layer 370 is formed in the opening 365 defined by the barrier ribs 361, and a common electrode 270 is formed on the barrier ribs 361 and on the organic emission layer 370.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A polymer substrate having a weight loss of less than about 1% based on an initial weight at a temperature ranging from about 420° C. to about 600° C.

2. The polymer substrate of claim 1, wherein the weight loss ranges from about 0.000001% to about 0.95% based on an initial weight.

3. The polymer substrate of claim 1, wherein the polymer substrate has a thermal expansion coefficient ranging from about 1 ppm/° C. to about 50 ppm/° C.

4. A method of producing a polymer substrate, comprising:
preparing a polymer layer; and
annealing the polymer layer at a temperature higher than about 350° C.

5. The method of claim 4, wherein the annealing of the polymer layer is performed at a temperature ranging from about 350° C. to about 500° C.

6. The method of claim 4, wherein the annealed polymer layer has a thermal expansion coefficient ranging from about 1 ppm/° C. to about 50 ppm/° C.

7. The method of claim 4, wherein the annealed polymer layer has a weight loss of less than about 1% based on an initial weight at a temperature ranging from about 420° C. to about 600° C.

8. The method of claim 4, further comprising forming a substrate protective layer on the polymer layer after the annealing of the polymer layer.

9. A display device, comprising:
a polymer substrate having a weight loss of less than about 1% based on an initial weight at a temperature ranging from about 420° C. to about 600° C.; and
an electronic device arranged on the polymer substrate.

10. The display device of claim 9, wherein the weight loss ranges from about 0.000001% to about 0.95% based on an initial weight.

11. The display device of claim 9, wherein the polymer substrate has a thermal expansion coefficient of about 1 ppm/° C. to about 50 ppm/° C.

12. The display device of claim 9, wherein the electronic device includes at least one of a thin film transistor and an organic light emitting element.

13. The display device of claim 12, wherein the thin film transistor comprises:
a control electrode;
a semiconductor overlapping the control electrode;
a gate insulating layer arranged between the control electrode and the semiconductor; and
an input electrode and an output electrode electrically connected to the semiconductor, wherein the gate insulating layer comprises tetraethyl orthosilicate (TEOS).

14. A method for manufacturing a display device, comprising:
preparing a polymer substrate;
annealing the polymer substrate at a temperature greater than about 350° C.; and
forming an electronic device on the annealed polymer substrate.

15. The method of claim 14, wherein the annealing of the polymer substrate is performed at a temperature ranging from about 350° C. to about 500° C.

16. The method of claim 14, wherein the electronic device is produced at a temperature greater than about 350° C.

17. The method of claim 16, wherein the forming the electronic device comprises forming a gate insulating layer, the gate insulating layer comprises tetraethyl orthosilicate (TEOS) at a temperature greater than about 350° C.

18. The method of claim 14, further comprising forming a substrate protective layer on the polymer substrate after the annealing of the polymer substrate.

19. A display device, comprising:
a polymer substrate having a thermal expansion coefficient ranging from 1 ppm/° C. to 50 ppm/° C.,
a thin film transistor formed on the polymer substrate, and
an organic light emitting element electrically connected to the thin film transistor.

20. The display device of claim 19, wherein the thin film transistor comprises:
a control electrode;
a semiconductor overlapping the control electrode;
a gate insulating layer arranged between the control electrode and the semiconductor; and
an input electrode and an output electrode electrically connected to the semiconductor.

21. The display device of claim 20, wherein the gate insulating layer comprises tetraethyl orthosilicate (TEOS).
